(19) United States
(12) Patent Application Publication
(10) Pub. No.: US 2005/0206466 A1
(43) Pub. Date: Sep. 22, 2005

(54) Refresh oscillator

(75) Inventors: Young Chul Sohn, Seoul (KR); Ja Seung Gou, Kyungki-do (KR)

Correspondence Address: MAYER, BROWN, ROWE & MAW LLP, 1909 K STREET, N.W., WASHINGTON, DC, 20006, US

(73) Assignee: Hynix Semiconductor Inc.

(21) Appl. No.: 11/081,725

(22) Filed: Mar. 17, 2005

(30) Foreign Application Priority Data
Mar. 17, 2004 (KR) 2004-18067

(51) Int. Cl. H03B 1/00

(52) U.S. Cl. 331/185

(57) ABSTRACT

The present invention relates to a refresh oscillator, and more specifically, to a refresh oscillator in which an oscillation cycle can vary according to variation in temperature of DRAM devices. According to the present invention, the refresh oscillator comprises a biasing circuit for generating a bias using a current mirror, a temperature compensation circuit for compensating for variation in the bias depending upon variation in temperature by controlling a resistance ratio, and an oscillator, which is driven by the bias compensated for by the temperature compensation circuit, thus generating an output signal that varies depending upon variation in temperature. Accordingly, since an oscillation cycle can be changed depending upon variation in temperature, the refresh oscillator can be applied to a design of all DRAM circuits for low power consumption.

### BACKGROUND

1. Field of the Invention

The present invention relates to a refresh oscillator, and more specifically, to a refresh oscillator in which an oscillation cycle can vary according to variation in temperature of DRAM devices.

2. Discussion of Related Art

DRAM devices have their stored data lost after a predetermined time elapses. In order to secure a data retention characteristic, an operation for refreshing the stored data is performed by activating a bit line sense amplifier. In order to secure the operational cycle of self refresh in which a refresh operation is repeated after a predetermined time elapses, a self-refresh oscillator is used. The self-refresh oscillator serves to generate a signal of a given cycle and decide a self refresh cycle using the signal.

FIG. 1 is a circuit diagram illustrating the construction of a conventional refresh oscillator that outputs a signal of a predetermined cycle even in the case of variation in a power source voltage VDD.

A biasing circuit 10 includes first and second current mirrors 11 and 12. The biasing circuit 10 sets first and second biases BIAS1 and BIAS2 to have a level in which PMOS transistors P101 to P104 and NMOS transistors N101 and N102 operate in a saturation region although the power source voltage VDD is changed. The first current mirror 11 includes the first and third PMOS transistors P101 and P103 connected between the power supply terminal VDD and a first node Q101 in a serial manner, and the second and fourth PMOS transistors P102 and P104 connected between the power supply terminal VDD and a second node Q102. The first current mirror 11 is constructed so that the first to fourth PMOS transistors P101 to P104 are driven according to an electric potential of the first node Q101. The second current mirror 12 includes the first NMOS transistor N101 connected between the first node Q101 and a third node Q103, and the second NMOS transistor N102 connected between the second node Q102 and a ground terminal VSS. The second current mirror 12 is constructed so that the first and second NMOS transistors N101 and N102 are driven according to an electric potential of the second node Q102. Further, a plurality of resistors R11 to R104 are connected between the third node Q103 and the ground terminal VSS in a serial manner. Fuses F101 to F103 are respectively connected between the resistors R101 to R103. Thus, since the values of the resistors are controlled depending upon whether the fuses F101 to F103 are cut, the electric potential of the first node Q101 is controlled. In this case, the electric potential of the first node Q101 becomes a first bias BIAS1, and the electric potential of the second node Q102 becomes a second bias BIAS2.

The start-up circuit 20 is a circuit for stabilizing an initial operation of the biasing circuit 10. The start-up circuit 20 includes a fifth PMOS transistor P105 connected between the power supply terminal VDD and a fourth node Q104, a fourth NMOS transistor N104 connected between the fourth node Q104 and a ground terminal VSS, and a third NMOS transistor N103 connected between the power supply terminal VDD and the first node Q101. At this time, the fifth PMOS transistor P105, the third NMOS transistor N103 and the fourth NMOS transistor N104 are each driven according to an electric potential of the fourth node Q104.

An oscillator 30 includes a plurality of inverters I101 to I105, and is driven according to the first and second biases BIAS1 and BIAS2, thus outputting consecutive pulses. The oscillator 30 includes PMOS transistors P106 to P110, which are connected between a power supply terminal VDD and pull-up elements of the inverters I101 to I105, respectively, and driven according to the first bias BIAS1, and NMOS transistors N105 to N109, which are connected between pull-down elements of the inverters I101 to I105 and the ground terminal VSS, respectively, and driven according to the second bias BIAS2. Thus, the oscillator 30 controls the current necessary for the operation of the inverters I101 to I105 using the PMOS transistors P106 to P110 and the NMOS transistors N105 to N109. Meanwhile, the inverters I101 to I105 constituting the oscillator 30 have an output of the previous stage becoming the input of a next stage, and the output of the last stage becoming the input of the foremost stage while becoming the output of the oscillator.

The refresh oscillator constructed above according to the present invention generates the first and second biases BIAS1 and BIAS2 using the first and second current mirrors 11 and 12 of the biasing circuit 10. The first and second PMOS transistors P101 and P102 and the third and fourth PMOS transistors P103 and P104, which constitute the first current mirror 11, are driven as a PMOS transistor pair, respectively, according to the electric potential of the first node Q101. As such, by constructing two pairs of the PMOS transistors, it is possible to output the first bias BIAS1, which is constant regardless of variation in the power source voltage VDD. Furthermore, the first and second NMOS transistors N101 and N102 constituting the second current mirror 12 are driven according to the electric potential of the second node Q102 as a NMOS transistor pair. Meanwhile, since the plurality of the resistors R101 to R104 are controlled depending upon whether the fuses F101 to F103 are cut, the values of the resistors are changed. It is thus possible to control the first bias BIAS1.

According to variation in the power source voltage VDD, the first and second biases BIAS1 and BIAS2 are set to have a level in which the PMOS transistors P101 to P104 and the NMOS transistors N101 and N102 operate in a saturation region. Since the inverters I101 to I105 of the oscillator 30 are operated in the same current by means of the first and second biases BIAS1 and BIAS2 regardless of variation in the power source voltage VDD, the cycle of the oscillator becomes constant. Further, since the first and second biases BIAS1 and BIAS2 operate in the saturation region not a linear region, they can operate at a voltage level of the sum of the threshold voltages of the PMOS transistors P106 to P110 and the NMOS transistors N105 to N109, e.g., even at a low power source voltage VDD of about 1.4V.

Meanwhile, the start-up circuit 20 is a circuit for stabilizing an initial operation of the biasing circuit 10. The operation of the start-up circuit 20 will be below described. In a state where the power source voltage VDD is low, if an electric potential of the fourth node Q104 is low when the first bias BIAS1 is around 0V, the electric potential of the fourth node Q104 is raised by turning on the fifth PMOS transistor P105. As the electric potential of the fourth node Q104 rises, the third and fourth NMOS transistors N103 and N104 are turned on to increase the first bias BIAS1. Since the fourth NMOS transistor N104 is turned on, however, the electric potential of the fourth node Q104 is lowered to turn on the fifth PMOS transistor P105 and to turn off the third NMOS transistor N103, thus lowering the first bias BIAS1. By means of the above operation, the first bias BIAS1 keeps a constant electric potential. The first to fourth PMOS transistors P101 to P104 of the first current mirror 11 are turned on by means of this constant electric potential.

In self refresh operation using the output signal of the refresh oscillator, the degree in which data is lost varies in proportion to temperature. That is, there is a tendency that as temperature becomes low, a data retention time increases in proportion to a log scale. Accordingly, for a low-power operation, when temperature is low, the refresh cycle can be extended. Thus, since the number of the bit line sense amplifier that operates is reduced, current consumption can be reduced. Therefore, the refresh oscillator constructed above can be applied to a design of a low-power device.

Self refresh operation using the output signal of the refresh oscillator constructed and driven as above can output a signal of a constant cycle regardless of variation in the power source voltage and shows a characteristic in which the bias level varies according to temperature. However, since the temperature characteristic of the transistors constituting the biasing circuit 10 also varies, there is almost no change in the cycle of the oscillator according to temperature and the input power supply. In other words, since there is almost no change in the cycle of the oscillator according to variation in temperature, an error in the operation of a device depending on variation in temperature cannot be compensated for.

### SUMMARY OF THE INVENTION

Accordingly, the present invention has been made in view of the above problems, and it is an object of the present invention to provide a refresh oscillator in which an oscillation cycle can be controlled according to variation in temperature.

Another object of the present invention is to provide a refresh oscillator that can be applied to a low-power device by reducing current consumption.

To achieve the above object, according to the present invention, there is provided a refresh oscillator, comprising a biasing circuit for generating a bias voltage using a current mirror, a temperature compensation circuit for compensating for variation in the bias voltage depending upon variation in temperature, and an oscillator, which is driven by the bias voltage compensated for by the temperature compensation circuit, thus generating an output signal that varies depending upon variation in temperature.

The temperature compensation circuit comprises a first element connected between an output terminal of the biasing circuit and first node, and a second element connected between the first node and a ground terminal, wherein variation in the bias voltage is compensated for in such a way to be in proportion to or in inverse proportion to the variation in temperature according to a resistance ratio between the first and second elements.

The first and second elements comprise a transistor, a diode or a resistor.

The oscillator comprises a plurality of inverters which are connected, in series, from each other and wherein an output of a last inverter is connected to an input of a first inverter, and a plurality of PMOS transistors connected between a power supply terminal and the inverters, the PMOS transistors being driven according to a bias voltage, which has been compensated for in such a way to be in inverse proportion to variation in temperature through the temperature compensation circuit.

The plurality of the PMOS transistors has their sizes controlled in order to control the current driving ability.

The oscillator comprises a plurality of inverters which are connected, in series, from each other and wherein an output of a last inverter is connected to an input of a first inverter, and a plurality of NMOS transistors connected between the inverters and a ground terminal, the NMOS transistors being driven according to a bias voltage, which has been compensated for in such a way to be in proportion to variation in temperature through the temperature compensation circuit.

The biasing circuit comprises a first PMOS transistor connected between a first node and a power supply terminal, a second PMOS transistor connected between a second node and the power supply terminal, a first NMOS transistor connected between the first node and a ground terminal, a gate of the first NMOS transistor being connected to the first node, and a second NMOS transistor connected between the second node and the ground terminal.

The refresh oscillator further comprises a resistor connected between the second NMOS transistor and the ground terminal.

To achieve the above object, according to the present invention, there is provided a refresh oscillator, comprising a biasing circuit for generating a bias voltage using a current mirror, a temperature compensation circuit for compensating for variation of the bias voltage due to variation of temperature, and a ring oscillator for generating consecutive pulses in response to an output of the temperature compensation circuit.

The biasing circuit comprises a first PMOS transistor connected between a first node and a power supply terminal, a second PMOS transistor connected between a second node and the power supply terminal, a first NMOS transistor connected between the first node and a ground terminal, a gate of the first NMOS transistor being connected to the first node, and a second NMOS transistor connected between the second node and the ground terminal.

The temperature compensation circuit comprises a first element connected between an output terminal of the biasing circuit and a first node, and a second element connected between the first node and a ground terminal, wherein variation in the bias voltage is compensated for in such a way to be in proportion to or in inverse proportion to the variation in temperature according to a resistance ratio between the first and second elements.

The first and second elements comprise a transistor, a diode or a resistor.

### BRIEF DESCRIPTION OF THE DRAWINGS

FIG. 1 is a circuit diagram illustrating the construction of a refresh oscillator in the prior art;

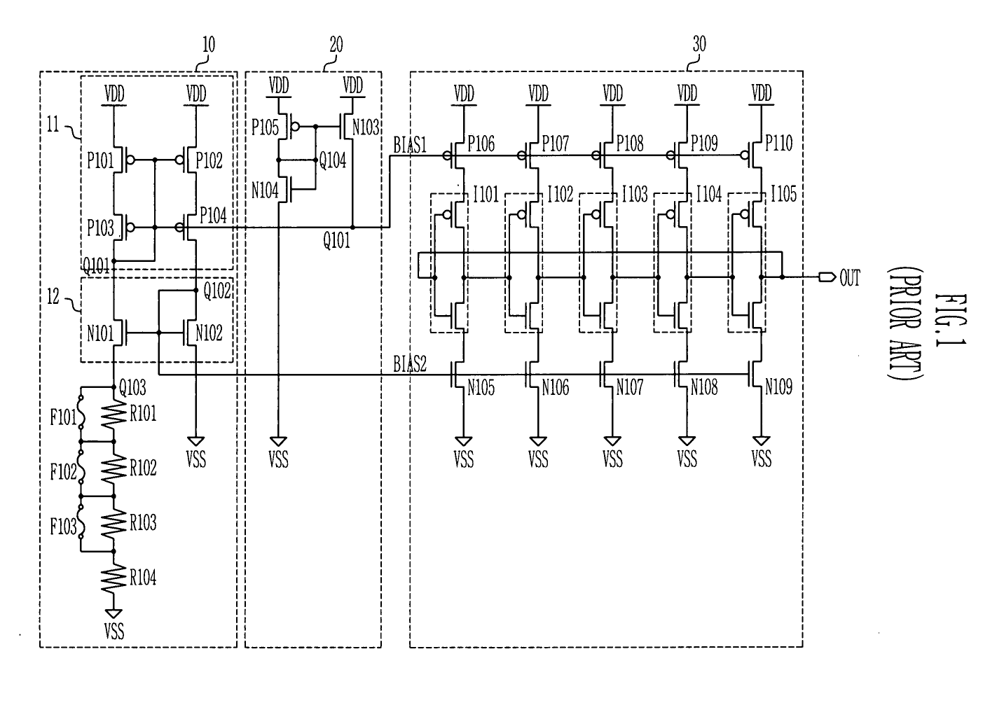

FIG. 2 is a circuit diagram illustrating the construction of a refresh oscillator according to a first embodiment of the present invention; and

FIG. 3 is a temperature compensation circuit according to a second embodiment of the present invention.

### DETAILED DESCRIPTION OF PREFERRED EMBODIMENTS

Now, the preferred embodiments according to the present invention will be described with reference to the accompanying drawings.

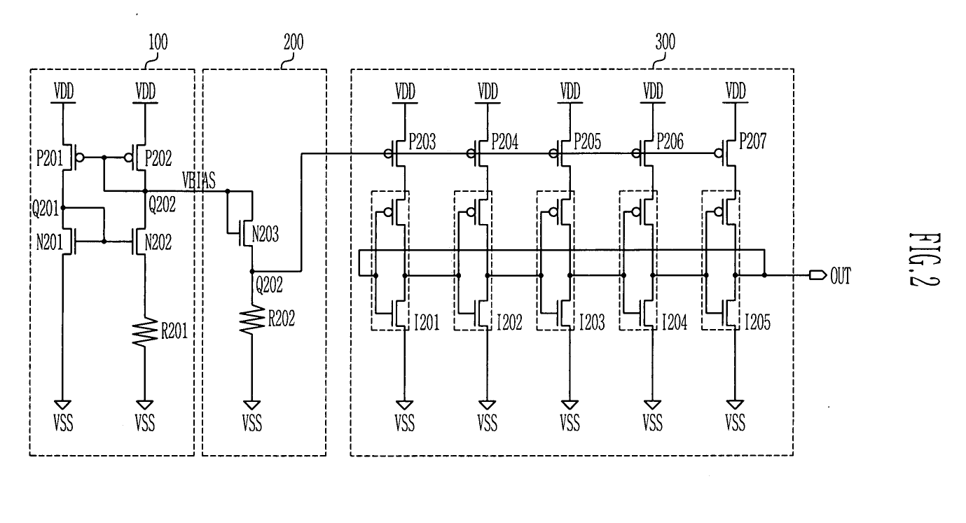

FIG. 2 is a circuit diagram illustrating the construction of a refresh oscillator in which an oscillation cycle can be controlled according to variation in temperature using a temperature compensation circuit according to the present invention.

Referring to FIG. 2, a biasing circuit 100 serves to generate a bias voltage VBIAS using a current mirror. The construction of the biasing circuit 100 will be below described. A first PMOS transistor P201 that is driven according to an electric potential of a second node Q202 is connected between a power supply terminal VDD and a first node Q201. A first NMOS transistor N201 that is driven according to an electric potential of the first node Q201 is connected between the first node Q201 and a ground terminal VSS. Further, a second PMOS transistor P202 that is driven according to the electric potential of the second node Q202 is connected between the power supply terminal VDD and the second node Q202. A second NMOS transistor N202 and a first resistor R201, which are driven according to the electric potential of the first node Q201, are serially connected between the second node Q202 and the ground terminal VSS. At this time, the electric potential of the second node Q202 becomes a bias voltage VBIAS, which is controlled by a first resistor R201.

A temperature compensation circuit 200 is a circuit for compensating for the bias voltage VBIAS, which varies according to variation in temperature. The temperature compensation circuit 200 includes a third NMOS transistor N203 connected between the second node Q202 and a third node Q203 and having a gate electrode connected to the second node Q202, and a second resistor R202 connected between the third node Q203 and the ground terminal VSS. The temperature compensation circuit 200 compensates for variation in the bias voltage VBIAS by controlling the resistance ratio between the third NMOS transistor N203 and the second resistor R202 according to variation in the bias voltage VBIAS depending on temperature. Accordingly, the temperature compensation circuit 200 can generate an output that is in inverse proportion to an increase in temperature and can generate an output that is in proportion to an increase in temperature. It is also to be noted that the third NMOS transistor N203 and the second resistor R202 are only examples, but can include load means such as a resistor, a transistor and a diode.

An oscillator 300 such as a ring oscillator includes a plurality of inverters I201 to I205. The oscillator 300 is driven according to the bias voltage VBIAS whose variation in a level is compensated for according to variation in temperature through the temperature compensation circuit 200, thus outputting consecutive pulses. PMOS transistors P203 to P207, which are driven according to the bias voltage VBIAS, are connected between the power supply terminal VDD and pull-up elements of the inverters I201 to I205, respectively. The oscillator 300 controls the current necessary for the operation of the inverters I201 to I205 using the PMOS transistors P203 to P207. The sizes of these PMOS transistors P203 to P207, such as a width and a length, can be controlled so that the current driving ability is changed according to variation in temperature. If a temperature rises, the gate level is lowered so as to improve the current driving ability. If a temperature lowers, the gate level is raised so as to lower the current driving ability. Meanwhile, in the inverters I201 to I205 constituting the oscillator 300, the output of the previous stage becomes the input of a next stage, and the output of the last stage becomes the input of the foremost stage and becomes the output of the oscillator 300.

A method of driving the refresh oscillator constructed above according to the present invention will now be described.

The bias voltage VBIAS is generated using the current mirror of the biasing circuit 100. The current flowing through the first node Q201 and the current flowing through the second node Q202, according to the current mirror, are the same. The level of the bias voltage VBIAS is decided by controlling a resistance value of the first resistor R201. However, the level of the bias voltage VBIAS varies according to variation in temperature. If a temperature rises, the resistance value of the first resistor R201 is increased, and the level of the bias voltage VBIAS is increased accordingly. On the contrary, if the temperature is lowered, the resistance value of the first resistor R201 is lowered and the level of the bias voltage VBIAS is lowered accordingly.

Variation in the level of the bias voltage VBIAS depending upon variation in temperature is compensated for by controlling the resistance ratio between the third NMOS transistor N203 and the second resistor R202 of the temperature compensation circuit 200. That is, if the resistance ratio is controlled, the current driving ability of these elements varies, and the level varies accordingly. It is thus possible to compensate for variation in the level of the bias voltage VBIAS depending upon variation in temperature. For example, if a temperature rises, the level of the bias voltage VBIAS also rises. It is thus required that the oscillation cycle be made fast if the temperature rises. To this end, the level of the bias voltage VBIAS, which is raised according to an increase in temperature, is controlled to have a characteristic that is in inverse proportion to the temperature by controlling the resistance ratio between the third NMOS transistor N203 and the second resistor R202 of the temperature compensation circuit 200. That is, the bias level divided by the third NMOS transistor N203 and the second resistor R202 is lowered by lowering the resistance value of the third NMOS transistor N203 and raising the resistance value of the second resistor R202. The bias voltage VBIAS, which is compensated for in such a way to have a characteristic that is in inverse proportion to a temperature by means of the temperature compensation circuit 200, is applied to the gate terminals of the PMOS transistors P203 to P207 of the oscillator 300, thereby driving the oscillator 300. Accordingly, the cycle of the output signal OUT becomes fast, and the oscillation cycle becomes also fast. However, if not only the level of the bias voltage VBIAS is compensated for in inverse proportion to a temperature, but also the gate levels of the PMOS transistors P203 to P207 are lowered, the current driving ability is further improved to make the oscillation cycle fast.

On the contrary, if the temperature is lowered, the level of the bias voltage VBIAS is lowered. If the temperature is lowered, the oscillation cycle has to be made slow. For this, the bias level that is divided by the third NMOS transistor N203 and the second resistor R202 is increased by increasing the resistance value of the third NMOS transistor N203 of the temperature compensation circuit 200 and lowering the resistance value of the second resistor R202. The bias VBIAS, which has been compensated for in such a way to have a characteristic that is in inverse proportion to a temperature by means of the temperature compensation circuit 200, is applied to the gate terminals of the PMOS transistors P203 to P207 of the oscillator 300, thereby driving the oscillator 300. Accordingly, the cycle of the output signal OUT becomes slow and the oscillation cycle becomes also slow. However, if not only the level of the bias voltage VBIAS is compensated for in inverse proportion to the temperature, but also the gate levels of the PMOS transistors P203 to P207 are increased, the current driving ability can be lowered to make the oscillation cycle slow.

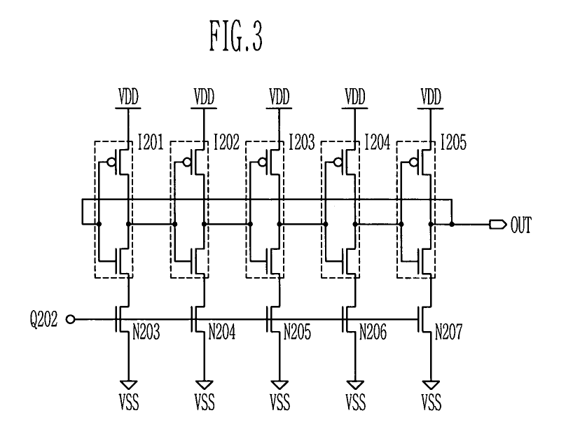

Meanwhile, according to second embodiment of the present invention, the bias VBIAS level can be compensated for in such a manner to have a characteristic in which the temperature compensation circuit 200 is proportional to a temperature. At this time, contrary to the aforementioned method, the resistance ratio between the third NMOS transistor N203 and the second resistor R202 is controlled. That is, if a temperature is increased, the resistance value of the third NMOS transistor N203 is controlled to be higher than the resistance value of the second resistor R202. If the temperature is lowered, the resistance value of the third NMOS transistor N203 is controlled to be lower than the resistance value of the second resistor R202. Further, in this case, the construction of the oscillator 300 has to be constructed differently. That is, the PMOS transistors P203 to P207 can be obviated, and a plurality of NMOS transistors N203 to N207 can be connected between the pull-down elements of the inverters I201 to I205 and the ground terminal VSS as shown in FIG. 3.

As described above, according to the present invention, a bias voltage, which varies depending upon a temperature, is compensated for in such a way to be in proportion or in inverse proportion to the temperature using a temperature compensation circuit. The compensated bias is used to drive an oscillator. Accordingly, the present invention is advantageous in that a refresh oscillator can be applied to a design of all DRAM circuits for low power consumption since an oscillation cycle can be changed depending upon variation in temperature.

Although the foregoing description has been made with reference to the preferred embodiments, it is to be understood that changes and modifications of the present invention may be made by the ordinary skilled in the art without departing from the spirit and scope of the present invention and appended claims.

1. A refresh oscillator, comprising:
a biasing circuit for generating a bias voltage using a current mirror;
a temperature compensation circuit for compensating for variation in the bias voltage depending upon variation in; and
an oscillator, which is driven by the bias voltage compensated for by the temperature compensation circuit, thus generating an output signal that varies depending upon variation in temperature.

2. The refresh oscillator as claimed in claim 1, wherein the temperature compensation circuit comprises:
a first element connected between an output terminal of the biasing circuit and a first node; and
a second element connected between the first node and a ground terminal,
wherein variation in the bias voltage is compensated for in such a way to be in proportion to or in inverse proportion to the variation in temperature according to a resistance ratio between the first and second elements.

3. The refresh oscillator as claimed in claim 2, wherein the first and second elements comprise a transistor, a diode or a resistor.

4. The refresh oscillator as claimed in claim 1, wherein the oscillator comprises:
a plurality of inverters which are connected, in series, from each other and wherein an output of a last inverter is connected to an input of a first inverter; and
a plurality of PMOS transistors connected between a power supply terminal and the inverters, the PMOS transistors being driven according to a bias voltage, which has been compensated for in such a way to be in inverse proportion to variation in temperature through the temperature compensation circuit.

5. The refresh oscillator as claimed in claim 4, wherein the plurality of the PMOS transistors has their sizes controlled in order to control the current driving ability.

6. The refresh oscillator as claimed in claim 1, wherein the oscillator comprises:
a plurality of inverters which are connected, in series, from each other and wherein an output of a last inverter is connected to an input of a first inverter; and
a plurality of NMOS transistors connected between the inverters and a ground terminal, the NMOS transistors being driven according to a bias voltage, which has been compensated for in such a way to be in proportion to variation in temperature through the temperature compensation circuit.

7. The refresh oscillator as claimed in claim 1, wherein the biasing circuit comprises:
a first PMOS transistor connected between a first node and a power supply terminal;
a second PMOS transistor connected between a second node and the power supply terminal;
a first NMOS transistor connected between the first node and a ground terminal;
a gate of the first NMOS transistor being connected to the first node; and
a second NMOS transistor connected between the second node and the ground terminal.

8. The refresh oscillator as claimed in claim 7, further comprising a resistor connected between the second NMOS transistor and the ground terminal.

9. A refresh oscillator, comprising:
a biasing circuit for generating a bias voltage using a current mirror;
a temperature compensation circuit for compensating for variation of the bias voltage due to variation of temperature; and
a ring oscillator for generating consecutive pulses in response to an output of the temperature compensation circuit.

10. The refresh oscillator as claimed in claim 9, wherein the biasing circuit comprises:
a first PMOS transistor connected between a first node and a power supply terminal;
a second PMOS transistor connected between a second node and the power supply terminal;
a first NMOS transistor connected between the first node and a ground terminal;
a gate of the first NMOS transistor being connected to the first node; and
a second NMOS transistor connected between the second node and the ground terminal.

11. The refresh oscillator as claimed in claim 9, wherein the temperature compensation circuit comprises:
a first element connected between an output terminal of the biasing circuit and a first node; and
a second element connected between the first node and a ground terminal,
wherein variation in the bias voltage is compensated for in such a way to be in proportion to or in inverse proportion to the variation in temperature according to a resistance ratio between the first and second elements.

12. The refresh oscillator as claimed in claim 11, wherein the first and second elements comprise a transistor, a diode or a resistor.
